(19) United States
(12) Patent Application Publication
(10) Pub. No.: US 2015/0236055 A1
(43) Pub. Date: Aug. 20, 2015

(54) ARRAY SUBSTRATE AND METHOD OF MANUFACTURING THE SAME, AND DISPLAY APPARATUS

(71) Applicant: BOE TECHNOLOGY GROUP CO., LTD.

(72) Inventors: Feng Zhang, Beijing (CN); Zhanfeng Cao, Beijing (CN); Qi Yao, Beijing (CN); Chuanxiang Xu, Beijing (CN)

(21) Appl. No.: 14/316,021

(22) Filed: Jun. 26, 2014

(30) Foreign Application Priority Data
Feb. 20, 2014 (CN) 201410057956.5

(51) Int. Cl. H01L 27/12; G02F 1/1362; G02F 1/1333; G02F 1/1368

(52) U.S. Cl. CPC H01L 27/1248; G02F 1/1368; G02F 1/136286; G02F 1/133345; H01L 27/124; H01L 27/1288

(57) ABSTRACT

Embodiments of the present invention provide an array substrate and a method of manufacturing the same, and a display apparatus. The array substrate includes: a substrate; thin film transistors, data lines, gate lines disposed on the substrate; an interlayer insulating layer, disposed below the pixel electrodes, and provided with insulating raised strips protruding in a thickness direction of the substrate towards a space between adjacent pixel electrodes, wherein a projection of each raised strip on the substrate is not overlapped with those of pixel electrodes adjacent thereto in the thickness direction. When the array substrate is applied to a display apparatus, an interference of electric field between the adjacent pixel electrodes can be reduced, thereby avoiding phenomena such as color mixing and light leakage between two adjacent pixel units, and improving display effect of the display apparatus.

### CROSS-REFERENCE TO RELATED APPLICATION

This application claims the benefit of Chinese Patent Application No. 201410057956.5 filed on Feb. 20, 2014 in the State Intellectual Property Office of China, the whole disclosure of which is incorporated herein by reference.

### BACKGROUND OF THE INVENTION

1. Field of the Invention

Embodiments of the present invention relate to field of display technique, in particular, to an array substrate and a method of manufacturing the same, and a display apparatus.

2. Description of the Related Art

With development and advancement of thin film transistor liquid crystal display (TFT-LCD Display) technique, a liquid crystal display apparatus has become a mainstream display apparatus in usual display field instead of a cathode ray tube display apparatus.

Currently, in order to improve a quality of images displayed by the liquid crystal display apparatus, a resolution of the liquid crystal display apparatus is continuously increased so as to offer more clear and vivid display images to customers. The resolution is defined as the number of pixels per inch area in the liquid crystal display apparatus. Thus, the higher the resolution is, the smaller a size of a pixel unit in the liquid crystal display apparatus is, and accordingly, as shown in FIG. 1, a spacing d between pixel electrodes 50 in two adjacent pixel units is becoming smaller and smaller. When an operating voltage is applied to the pixel electrodes 50, electric fields between adjacent pixel electrodes 50 will be interfered with each other (as shown by a arrow in the figure), thereby affecting the quality of the displayed images.

For example, as shown in FIG. 2, when only liquid crystal molecules 90 corresponding to a certain pixel unit (denoted by a) are required to be deflected, while liquid crystal molecules 90 corresponding to a pixel unit (denoted by b) adjacent to the pixel unit a are not required to be deflected, electric fields between adjacent pixel electrodes 50 will be interfered with each other due to a very small spacing between the pixel unit a and the pixel unit b, resulting in that the liquid crystal molecules 90 between the two adjacent pixel units a and b, and liquid crystal molecules corresponding to an edge of the pixel unit b adjacent to the pixel unit a will be deflected, so that phenomena such as color mixing and light leakage will occur in adjacent pixel units in the liquid crystal display apparatus, thereby affecting display effect of the liquid crystal display apparatus.

### SUMMARY OF THE INVENTION

According to an embodiment of one aspect of the present invention, there is provided an array substrate, including: a substrate; thin film transistors, data lines, gate lines and pixel electrodes disposed on the substrate, wherein the gate lines extend in parallel with a first direction, and the data lines extend in parallel with a second direction; an interlayer insulating layer, disposed below the pixel electrodes, and provided with insulating raised strips protruding in a thickness direction of the substrate towards a space between adjacent pixel electrodes, wherein a projection of each raised strip on the substrate in the thickness direction is not overlapped with those of the adjacent pixel electrodes.

An embodiment of another aspect of the present invention provides a display apparatus including the array substrate as described above.

An embodiment of yet another aspect of the present invention provides a method of manufacturing an array substrate, including steps: forming thin film transistors, data lines, gate lines and pixel electrodes on a substrate, wherein the gate lines extend in parallel with a first direction, and the data lines extend in parallel with a second direction; forming an interlayer insulating layer including insulating raised strips on the substrate formed with the thin film transistors, the data lines, and the gate lines thereon; and forming pixel electrodes on the substrate formed with interlayer insulating layer including the raised strips thereon, wherein the raised strips protrude in a thickness direction of the substrate towards a space between adjacent pixel electrodes, and a projection of each raised strip on the substrate in the thickness direction is not overlapped with those of the adjacent pixel electrodes.

### BRIEF DESCRIPTION OF THE DRAWINGS

The above and other features of the invention will become more apparent by describing in detail exemplary embodiments thereof with reference to the accompanying drawings, in which: FIG. 1 is a cross sectional view showing a structure of an array substrate in prior arts;

FIG. 2 is a schematic simulation view showing color mixing and light leakage occurred due to an interference of electric fields between adjacent pixel units in prior arts;

FIG. 3 is a plan view showing a structure of an array substrate according to an embodiment of the present invention;

FIG. 4 is a cross sectional view showing a structure of an array substrate according to an exemplary embodiment of the present invention, in particular, showing partially sectioned structural views in an A-A′ direction and a C-C′ direction in FIG. 3;

FIG. 5(a) is a schematic view showing relative positions of pixel electrodes and first raised strips according to an exemplary embodiment of the present invention;

FIG. 5(b) is a schematic view showing relative positions of pixel electrodes and first raised strips according to another exemplary embodiment of the present invention;

FIG. 6 is a schematic simulation view showing an effect of reducing an interference of electric fields between adjacent pixel electrodes in an array substrate provided in an embodiment of the present invention;

FIG. 7 is a cross sectional view showing a structure of an array substrate according to another exemplary embodiment of the present invention, in particular, showing a partially sectioned structural view in a B-B′ direction in FIG. 3;

FIG. 8(a) is a schematic view showing relative positions of pixel electrodes and second raised strips according to an exemplary embodiment of the present invention;

FIG. 8(b) is a schematic view showing relative positions of pixel electrodes and second raised strips according to another exemplary embodiment of the present invention;

FIG. 9(a) is a cross sectional view showing a structure of an array substrate including a common electrode according to a first exemplary embodiment of the present invention, in particular, showing partially sectioned structural views in an A-A′ direction and a C-C′ direction in FIG. 3;

FIG. 9(b) is a cross sectional view showing a structure of an array substrate including a common electrode according to a second exemplary embodiment of the present invention, in particular, showing partially sectioned structural views in an A-A′ direction and a C-C′ direction in FIG. 3;

FIG. 9(c) is a cross sectional view showing a structure of an array substrate including a common electrode according to a third exemplary embodiment of the present invention, in particular, showing partially sectioned structural views in an A-A′ direction and a C-C′ direction in FIG. 3;

FIG. 9(d) is a cross sectional view showing a structure of an array substrate including a common electrode according to a fourth exemplary embodiment of the present invention, in particular, showing partially sectioned structural views in an A-A′ direction and a C-C′ direction in FIG. 3;

FIGS. 10 to 15 are sectional views showing manufacturing processes of forming an interlayer insulating layer including raised strips on a substrate formed with thin film transistors, data lines and gate lines thereon according to an exemplary embodiment of the present invention;

FIGS. 16 and 17 are sectional views showing manufacturing processes of forming a second insulating layer of a positive photoresist material or a negative photoresist material on the substrate formed with the first insulating layer according to another exemplary embodiment of the present invention; and

FIG. 18 is a cross sectional view showing a structure of an array substrate including a common electrode according to a still further exemplary embodiment of the present invention.

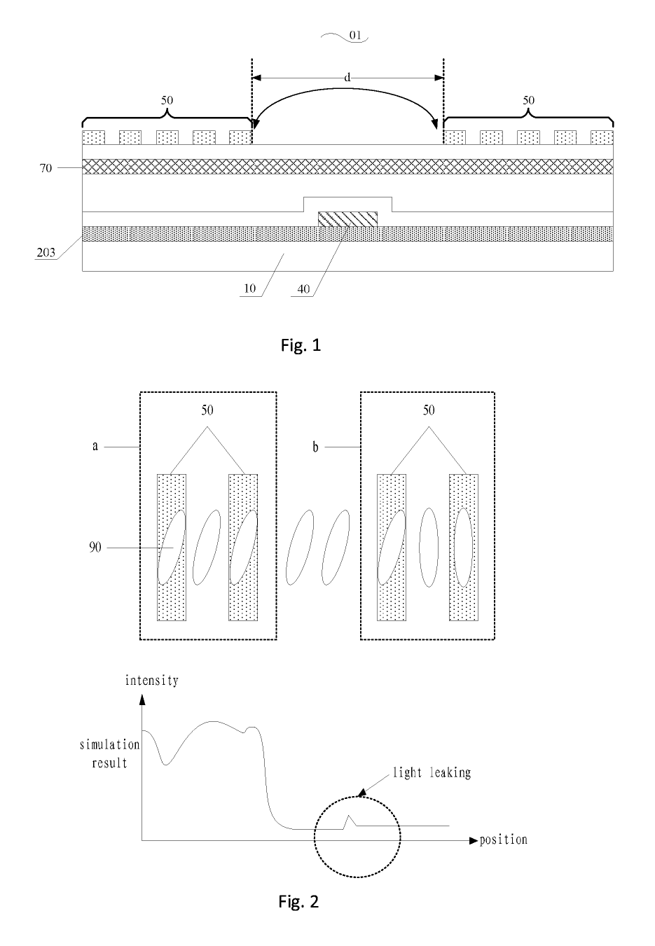

### REFERENCE NUMBERS

01-array substrate; 10-substrate; 20-thin film transistors; 202-drain; 203-gate insulating layer; 30-gate lines; 40-data lines; 50-pixel electrodes; 50h-height of a pixel electrode; 60-interlayer insulating layer; 601-first insulating layer; 602-second insulating layer; 610-raised strip; 611-first raised strip; 611h-height of a first raised strip; 612-second raised strip; 612h-height of a second raised strip; 70-common electrode; 80-passivation layer; 801-insulating material layer; 90-liquid crystal molecules; 100-half-tone mask; 100a-fully opaque portion; 100b-translucent portion; 100c-fully transparent portion; 110-positive photoresist; 111-negative photoresist; 110a-fully-remained portion; 110b-half-remained portion; 110c-fully-removed portion.

### DETAILED DESCRIPTION OF PREFERRED EMBODIMENTS OF THE INVENTION

Exemplary embodiments of the present invention will be described hereinafter in detail with reference to the attached drawings, wherein the like reference numerals refer to the like elements. The present invention may, however, be embodied in many different forms and should not be construed as being limited to the embodiment set forth herein; rather, these embodiments are provided so that the present invention will be thorough and complete, and will fully convey the concept of the disclosure to those skilled in the art.

According to a general inventive concept of the present invention, there is provided an array substrate, including: a substrate; thin film transistors, data lines, gate lines and pixel electrodes disposed on the substrate, wherein the gate lines extend in parallel with a first direction, and the data lines extend in parallel with a second direction; an interlayer insulating layer, disposed below the pixel electrodes, and provided with insulating raised strips protruding in a thickness direction of the substrate towards a space between adjacent pixel electrodes, wherein a projection of each raised strip on the substrate in the thickness direction is not overlapped with those of the adjacent pixel electrodes.

When the above array substrate is used in a display apparatus, the raised strips disposed in a region between two pixel electrodes adjacent to each other in the first direction can be used to isolate the interference of electric fields between the two pixel electrodes, so that deflection of liquid crystal molecules corresponding to a pixel electrode can be prevented from being affected by another pixel electrode adjacent thereto, thereby avoiding phenomena such as color mixing and light leakage occurring between adjacent pixel units in the display apparatus including the array substrate, and improving display effects of the display apparatus.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

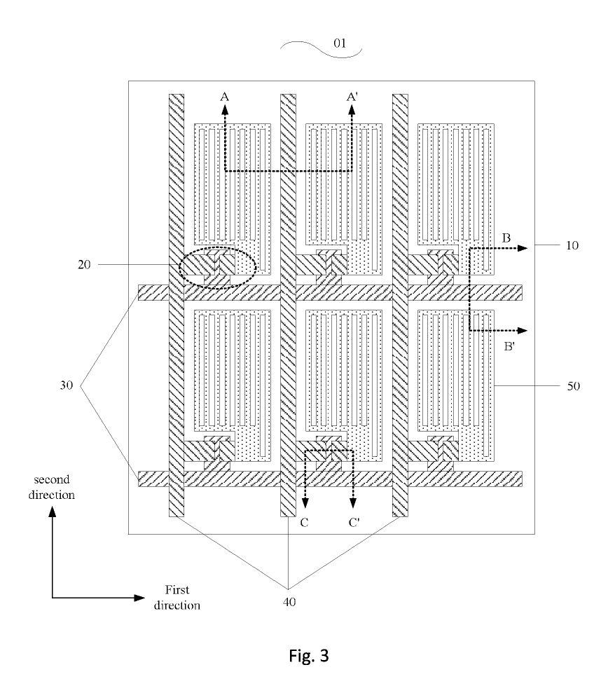

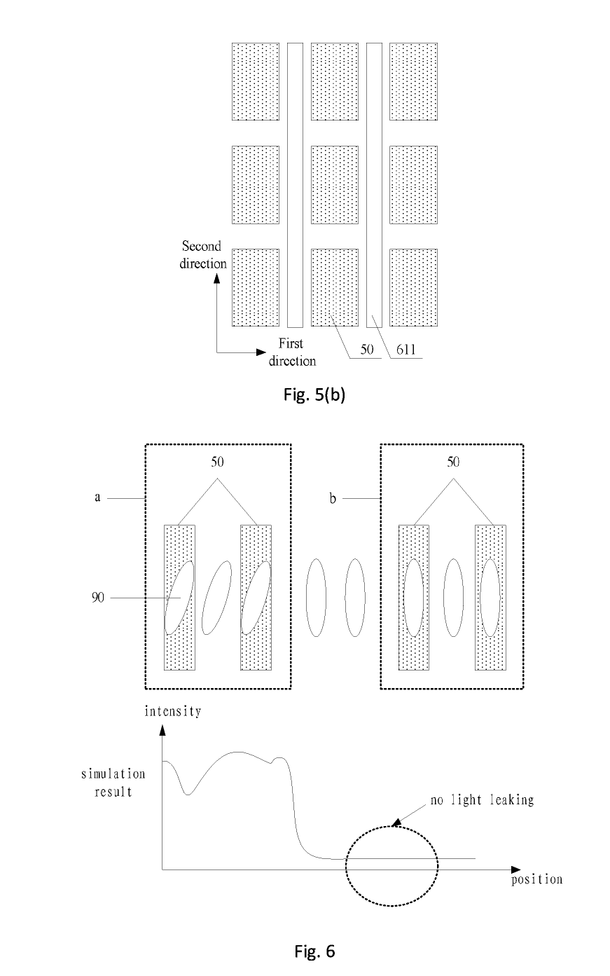

Exemplary embodiments of the present invention provide an array substrate 01. As shown in FIG. 3˜FIG. 5(b), the array substrate 01 includes: a substrate 10, thin film transistors 20, data lines 40, gate lines 30 and pixel electrodes 50 disposed on the substrate 10; the array substrate 01 further includes an interlayer insulating layer 60 including raised strips (not indicated in FIG. 3) and disposed below the pixel electrodes 50; the raised strips includes a plurality of first raised strips 611, which are at least disposed in a region where adjacent pixel electrodes 50 are adjacent to each other in a first direction; wherein the first raised strip 611 is not overlapped with adjacent pixel electrodes 50 adjacent thereto, and a height 611h of the first raised strip in a direction perpendicular to the substrate 10 is larger than a height 50h of the pixel electrode.

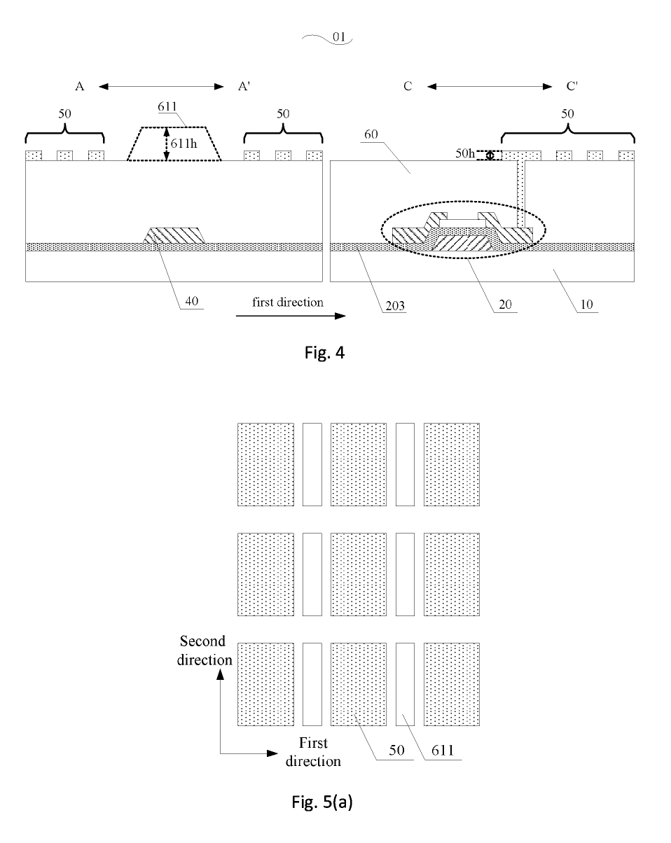

Note that, firstly, as shown in FIG. 4, the first raised strip 611 is a portion of the interlayer insulating layer 60 protruding relative to a flat region thereof, and the height 611h of the first raised strips is a height of the first raised strips 611 relative to the flat region of the interlayer insulating layer 60, that is, a height protruding from the flat region in a thickness direction of the substrate 10 towards a space between adjacent pixel electrodes.

Secondly, the number of the interlayer insulating layers 60 is not limited. In case that the interlayer insulating layer 60 includes at least two insulating layers, and in view of simplifying manufacturing processes of the interlayer insulating layers 60 as much as possible, the raised strips only need to be disposed on one insulating layer in order to achieve an effect of isolating interference of electric fields between the adjacent pixel electrodes 50.

Thirdly, as shown in FIG. 5(a), the first raised strips 611 of the raised strips can be only disposed between two pixel electrodes 50 adjacent to each other in a first direction, that is, there is a space between the first raised strips 611 in a second direction perpendicular to the first direction; alternatively, as shown in FIG. 5(b), the first raised strip 611 may be disposed between two columns of the pixel electrodes 50 extending in the second direction, in other words, two columns of the pixel electrodes 50 correspond to one first raised strip 611.

Fourthly, the principle by which the above the array substrate Olean reduce an interference of electric fields between pixel electrodes 50 in two adjacent pixel units so as to reduce the color mixing phenomenon between adjacent pixel units will be described as follows:

With reference to FIG. 3 and FIG. 4, in the array substrate 01, a plurality of pixel units are surrounded by crisscrossed data lines 40 and gate lines 30 and arranged in a matrix form, and when a size of the pixel unit surrounded by the data lines 40 and the gate lines 30 is continuously reduced to cause a distance between adjacent pixel electrodes 50 to be continuously reduced, a reduction in the distance between adjacent pixel electrodes 50 in the first direction is larger, that is, the interference of electric fields between the adjacent pixel electrodes 50 in the first direction is stronger, compared to adjacent pixel electrodes 50 in the second direction.

Thus, in the embodiment of the present invention, since there are disposed the first raised strips 611 between two pixel electrodes 50 adjacent to each other in the first direction, and the height 611h of the first raised strips in the direction perpendicular to the substrate 10 (i.e., the thickness direction of the substrate) is larger than the height 50h of the pixel electrodes, the interference of electric fields between adjacent pixel electrodes 50 in the first direction can be isolated remarkably, thereby avoiding phenomena such as color mixing and light leakage, and improving display effect of the display apparatus.

Considering that compared with the height 50h of the pixel electrodes, a larger height 611h of the first raised strips has a better effect of isolating the interference of electric fields between adjacent pixel electrodes 50, optionally the height 611h of the first raised strips is at least higher than the height 50h of the pixel electrodes by lnm.

Here, when the array substrate 01 is applied to a display apparatus and is operated, the display effect of display apparatus improved by the first raised strips 611 can be found with referenced to following simulation view:

As shown in FIG. 6, when the liquid crystal molecules 90 corresponding to a pixel electrode 50 within a pixel unit a are deflected, an interference of electric field, which is caused by the pixel electrode 50 to another pixel electrode 50 within a pixel unit b adjacent to the pixel unit a, can be reduced because of isolating effect provided by the first raised strips 611, thereby preventing liquid crystal molecules 90 between the adjacent pixel electrodes 50 and liquid crystal molecules corresponding to an edge of the pixel unit b adjacent to the pixel unit a from being deflected. When the array substrate 01 is applied to a display apparatus, corresponding macroscopic effects include reduction in color mixing between two adjacent pixel units and light leakage, and an improvement in display effect in the display apparatus.

Further, considering that when distances between the first raised strips 611 and adjacent pixel electrodes 50 adjacent thereto are smaller, a better effect of isolating the above interference of electric field can be achieved, thus widths of the first raised strips 611 in the first direction are set to be equal to or larger than those of the data lines 40 as shown in FIG. 4.

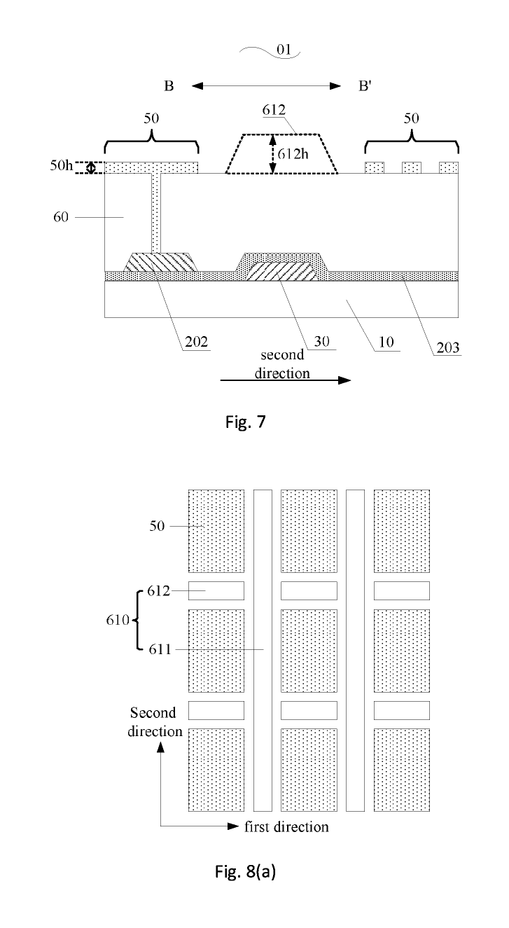

Furthermore, as shown in FIG. 7, when a size of the pixel unit surrounded by the data lines 40 and the gate lines 30 is continuously reduced to cause a distance between adjacent pixel electrodes 50 to be continuously reduced, a distance between adjacent pixel electrodes 50 in the second direction perpendicular to the first direction is also reduced, there is also some interference of electric field between the adjacent pixel electrodes 50 in the second direction.

In such a case, the raised strips 610 may further includes a plurality of second raised strips 612, which are at least disposed between the pixel electrodes 50 adjacent to each other in the second direction perpendicular to the first direction.

Preferably, the second raised strips 612 are not overlapped with adjacent pixel electrodes 50 adjacent thereto, and a height 612h of the second raised strips is larger than the height 50h of the pixel electrodes in the direction perpendicular to the substrate 10.

Here, in order to simplify processes of manufacturing the raised strips, the height 612h of the second raised strips are set to be the same as the height 611h of the above first raised strips.

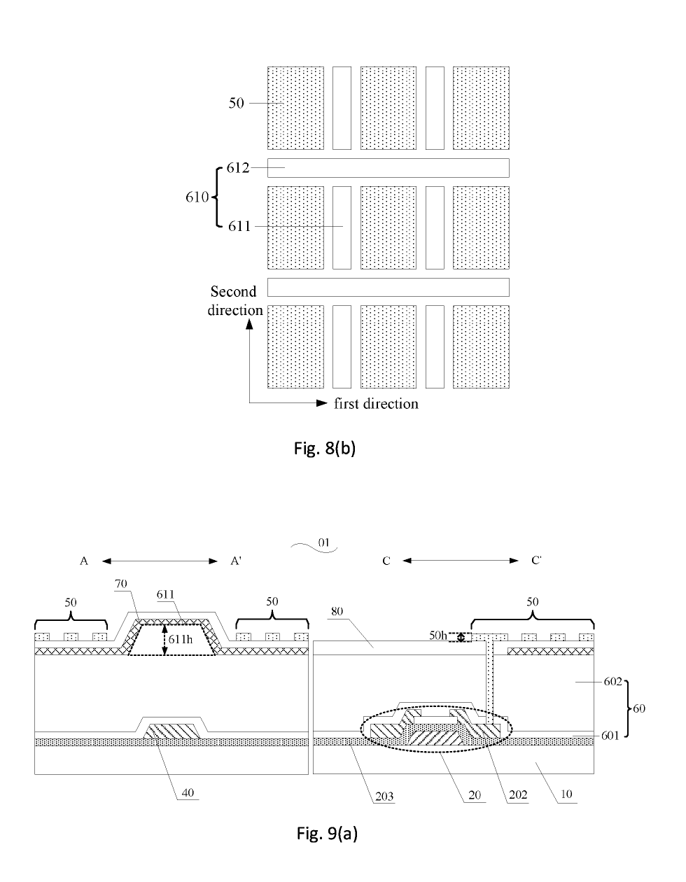

As can be seen from the above description, the second raised strips 612 and the first raised strips 611 are disposed in the same layer, and thus, as shown in FIG. 8(a), the second raised strips 612 of the raised strips 610 can be only disposed between the adjacent pixel electrodes 50 adjacent to each other in the second direction, that is, there is a space between the second raised strips 612 in the first direction; at this time, the first raised strip 611 may also be only disposed between the pixel electrodes 50 adjacent to each other in the first direction.

Alternatively, as shown in FIG. 8(b), the second raised strips 612 may be disposed between two rows of the pixel electrodes 50 extending in the first direction, that is, two rows of the pixel electrodes 50 correspond to one second raised strip 612; at this time, the first raised strips 611 may extend up to the second raised strips 612, that is, the first raised strips 611 and the second raised strips 612 form a grid pattern.

Further, considering that when distances between the second raised strips 612 and adjacent pixel electrodes 50 adjacent thereto are smaller, a better effect of isolating the above interference of electric field can be achieved, thus widths of the second raised strips 612 in the second direction are set to be equal to or larger than those of the gate lines 30.

In further alternative embodiments of the present invention, adjacent pixel electrodes 50 are arranged symmetrically relative to a midline of a corresponding one of the raised strips. Specifically, adjacent pixel electrodes 50 are arranged symmetrically relative to a midline of a corresponding one of the first raised strips 611 in the first direction, and adjacent pixel electrodes 50 are arranged symmetrically relative to a midline of a corresponding one of the second raised strips 612 in the second direction.

As such, the first raised strips 611 have the same effect of isolating the interference of electric field for two pixel electrodes 50 adjacent thereto, and the second raised strips 612 have the same effect of isolating the interference of electric field for two pixel electrodes 50 adjacent thereto. When the above array substrate is applied to a display apparatus, the color mixing phenomenon between adjacent pixel units in the display apparatus can be more effectively reduced, thereby improving display effects of the display apparatus.

Note that in the present invention, the protruding heights of the raised strip needs to be equal to or higher than those of the pixel electrodes, that is, surfaces of the raised strips far away from the interlayer insulating layer are in the same plane as surfaces of the pixel electrodes far away from the interlayer insulating layer, or protrude beyond a plane in which the surfaces of the pixel electrodes far away from the interlayer insulating layer are disposed. However, the raised strips may have lower protruding heights as long as the interference between pixel electrodes is within a tolerable range.

Moreover, the array substrate 01 may further include a common electrode 70, and in such a case, the interlayer insulating layer 60 is disposed between a pattern layer including the thin film transistors 20, the data lines 40 and the gate lines 30 and a pattern layer including the common electrode 70.

Of course, the array substrate 01 may further include a passivation layer 80 disposed between the pattern layer including the common electrode 70 and a pattern layer including the pixel electrodes 50.

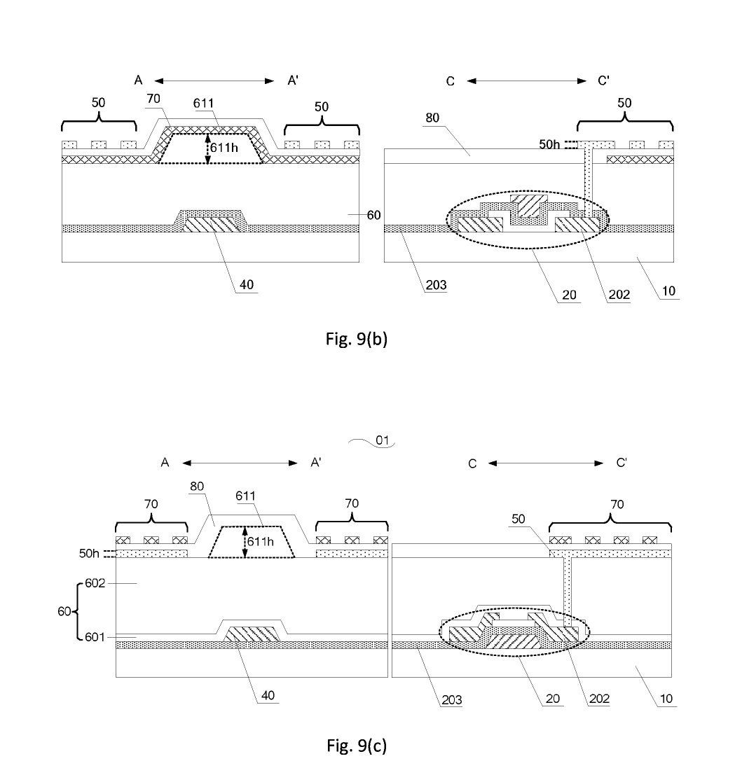

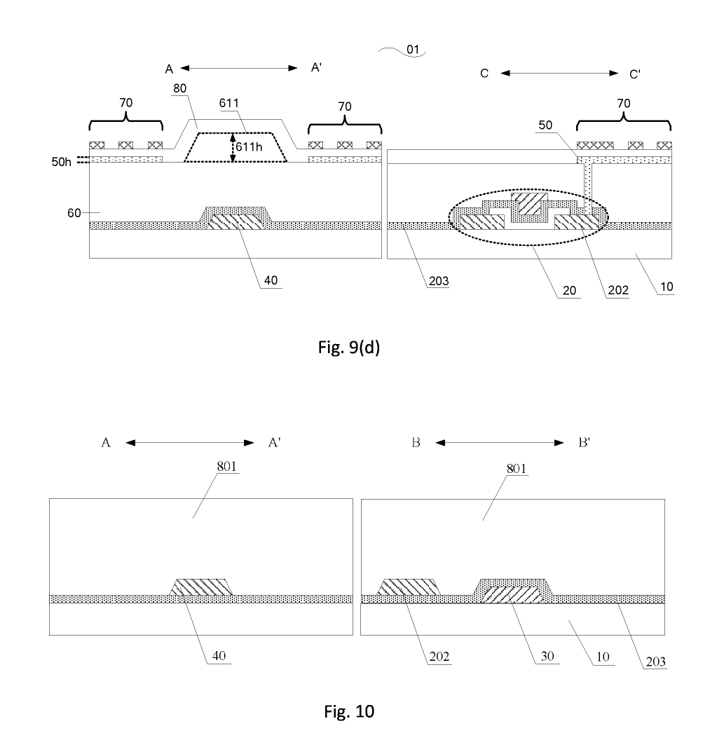

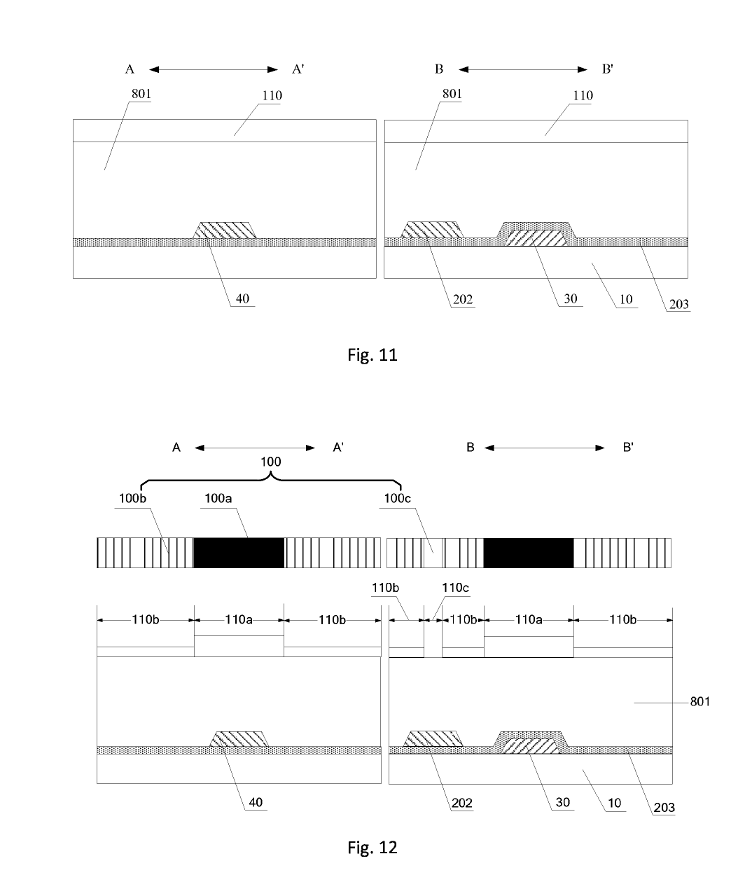

When the pattern layer including the pixel electrodes 50 is disposed over the pattern layer including the common electrode 70, since the pixel electrodes 50 need to be electrically connected with drains 202 of the thin film transistors 20, through holes are provided in the passivation layer 80 and the interlayer insulating layer 60 to expose the drains 202 as shown in FIG. 9(a) when the thin film transistors 20 in the array substrate 01 are bottom-gate type transistors; alternatively, through holes are provided in the passivation layer 80, the interlayer insulating layer 60 and the gate insulating layer 203 to expose the drains 202 as shown in FIG. 9(b) when the thin film transistors 20 in the array substrate 01 are top-gate type transistors.

Further, when widths of the first raised strips 611 are equal to or larger than those of the data lines 40 in the first direction, since the interlayer insulating layer 60 is disposed below the pattern layer including the common electrode 70, and spacing between the regions where the common electrode 70 and the data lines 40 are overlapped with each other can be increase by the first raised strips 611, thereby reducing parasitic capacitance of the regions where the common electrode 70 and the data lines 40 are overlapped with each other so as to reduce a whole energy consumption of the array substrate 01.

When the pattern layer including the pixel electrodes 50 is disposed below the pattern layer including the common electrode 70, since the pixel electrodes 50 need to be electrically connected with drains 202 of the thin film transistors 20, through holes are provided in the interlayer insulating layer 60 to expose the drains 202 as shown in FIG. 9(c) when the thin film transistors 20 in the array substrate 01 are bottom-gate type transistors; alternatively, through holes are provided in the interlayer insulating layer 60 and the gate insulating layer 203 to expose the drains 202 as shown in FIG. 9(d) when the thin film transistors 20 in the array substrate 01 are top-gate type transistors.

Further with reference to FIG. 9(a) and FIG. 9(c), the interlayer insulating layer 60 includes a first insulating layer 601 made of an inorganic material and a second insulating layer made 602 made of an organic resin material, which are sequentially disposed over the pattern layer including the thin film transistors 20, the data lines 40 and the gate lines 30, and the raised strips are disposed on the second insulating layer 602.

Since the organic resin material has a higher transparency, the heights of the raised strips can be made larger when the second insulating layer 602 is made of the organic resin material, while the first insulating layer 601 made of inorganic material can increase a bonding strength between the second insulating layer 602 and the pattern layer including the thin film transistors 20, the data lines 40 and the gate lines 30. Here, the bottom-gate type thin film transistor 20 is only described as an example, the present invention, however, is not limited to this.

Further, the organic resin material may include a positive photoresist material or a negative photoresist material.

The positive photoresist material is a material which is not dissolved in a developing solution before exposure and becomes dissolvable in the developing solution after exposure; the negative photoresist material is a material which is dissolvable in a developing solution before exposure and becomes indissolvable in the developing solution after exposure.

The positive photoresist or the negative photoresist formed on the first insulating layer 601 made of an inorganic material are exposed and developed by using their photosensitive characteristics, so as to quickly and easily form the second insulating layer 602 including the raised strips; meanwhile, since no etching process is needed when forming the raised strips on the second insulating layer 602, etching residue or non-uniformity of etching can be avoided when forming the raised strips having certain heights, thereby improving an overall quality of the interlayer insulating layer 60.

An embodiments of the present invention further provides a method of manufacturing the above array substrate 01, including steps of:

step S01 of forming thin film transistors 20, data lines 40 and gate lines 30 on a substrate 01;

step S02 of forming an interlayer insulating layer 60 including insulating raised strips on the substrate formed with thin film transistors 20, data lines 40 and gate lines 30 thereon; and

step S03 of forming pixel electrodes 50 on the substrate formed with interlayer insulating layer 60 including the raised strips thereon.

With reference to FIG. 4, the raised strips include a plurality of first raised strips 611, which are at least disposed in a region between adjacent pixel electrodes 50 adjacent to each other in a first direction, and the first raised strip 611 is not overlapped with adjacent pixel electrodes 50 adjacent thereto, and a height 611h of the first raised strip in a direction perpendicular to the substrate 10 is larger than a height 50h of the pixel electrode.

Here, with reference to FIG. 5(a), the first raised strip 611 may be only disposed in the region between adjacent pixel electrodes 50 adjacent to each other in the first direction, that is, there is a space between the first raised strips 611 in the second direction perpendicular to the first direction; alternatively, the first raised strip 611 may be disposed between two columns of the pixel electrodes 50 extending in the second direction as shown in FIG. 5(b).

Since there are disposed the first raised strips 611 between two pixel electrodes 50 adjacent to each other in the first direction, and the height 611h of the first raised strips in the direction perpendicular to the substrate 10 is larger than the height 50h of the pixel electrodes, the interference of electric field between adjacent pixel electrodes 50 in the first direction can be isolated remarkably, thereby avoiding phenomena such as color mixing and light leakage, and improving display effect of the display apparatus.

Furthermore, when a size of the pixel unit surrounded by the data lines 40 and the gate lines 30 is continuously reduced to cause a distance between adjacent pixel electrodes 50 to be continuously reduced, a distance between adjacent pixel electrodes 50 in the second direction perpendicular to the first direction is also reduced, there is also some interference of electric field between the adjacent pixel electrodes 50 in the second direction.

Considering that, as shown in FIG. 7, the raised strips 610 may further include a plurality of second raised strips 612. The step of forming the second raised strips 612 comprises forming the second raised strips 612 between two pixel electrodes 50 adjacent to each other in the second direction perpendicular to the first direction, while forming the first raised strip 611.

The second raised strip 612 is not overlapped with two adjacent pixel electrodes 50 adjacent thereto, and a height of the second raised strip 612 in a direction perpendicular to the substrate 10 is larger than a height of the pixel electrode 50.

Specifically, the step S02 of forming the interlayer insulating layer 60 including the insulating raised strips on the substrate formed with the thin film transistors 20, the data lines 40 and the gate lines 30 thereon includes steps of:

step S101 of forming an insulating material layer 801 on the substrate formed with a pattern layer including thin film transistors 20, the data lines 40 and the gate lines 30 thereon, as shown in FIG. 10;

step S102 of coating photoresist 110 on the substrate formed with the insulating material layer 801 thereon; and

step S103 of exposing and developing the substrate coated with the photoresist 110 thereon by using a half-tone mask 100 or a gray tone mask so as to form a photoresist fully-remained portion 110a, a photoresist half-remained portion, and a photoresist fully-removed portion 110c.

The photoresist fully-remained portion 110a corresponds to regions of the raised strips, the photoresist fully-removed portion 110c corresponds to drain regions 202 of the thin film transistors 20, and the photoresist half-remained portion 110b corresponds to other regions.

Here, the photoresist 110 includes positive photoresist, that is, the photoresist fully-remained portion 110a corresponds to a fully opaque portion 100a of the half-tone mask 100 or the gray tone mask, the photoresist half-remained portion 110b corresponds to a translucent portion 100b of the half-tone mask 100 or the gray tone mask, and the photoresist fully-removed portion 110c corresponds to a fully transparent portion 100c of the half-tone mask 100 or the gray tone mask.

The step S02 further includes a step S104 of etching the photoresist fully-removed portion 110c, the photoresist half-remained portion 110b, and the photoresist fully-remained portion 110a so as to form the interlayer insulating layer 60 including the raised strips.

Specifically, the above step S104 may include:

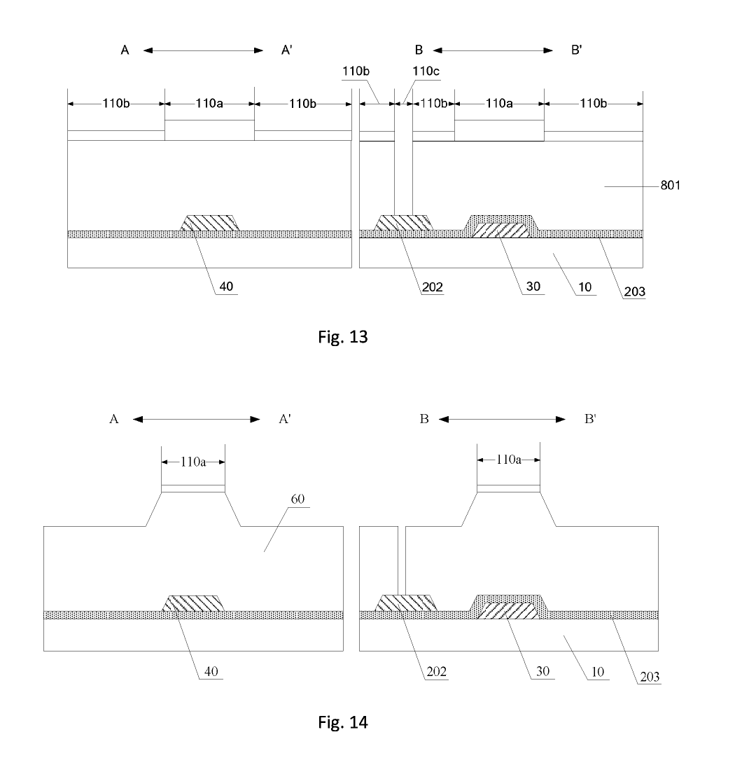

step S1041: as shown in FIG. 13, exposed portions of the insulating material layer 801 after removing the photoresist fully-removed portion 110c are etched to expose regions of the drains 202 of the thin film transistors 20;

step S1042: as shown in FIG. 14, the photoresist of the photoresist half-remained portion 110b is removed by using an ashing process, and then exposed the insulating material layer 801 is etched so as to form other flat regions of the interlayer insulating layer 60 by controlling process parameters such as etching time, etching rate and the like;

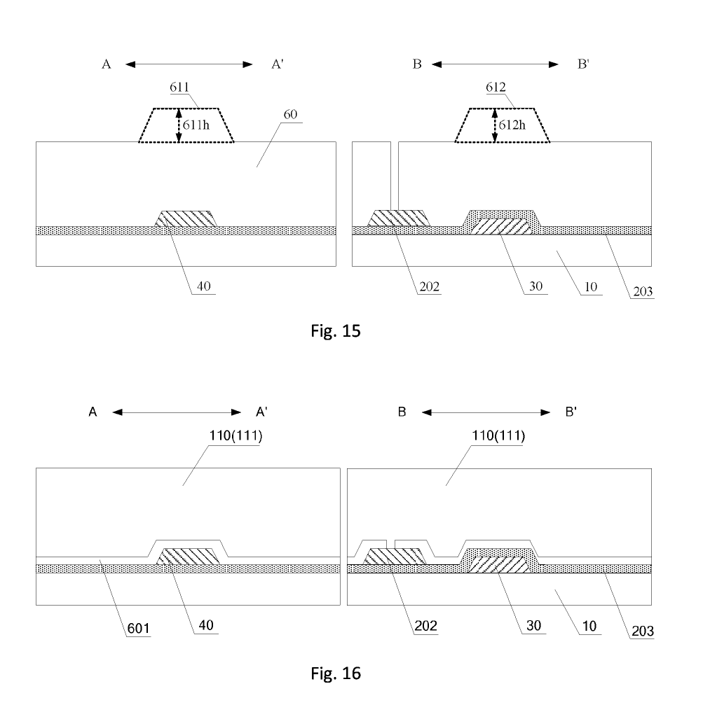

step S1043: as shown in FIG. 15, the photoresist fully-remained portion 110a is removed to form the interlayer insulating layer 60 including the raised strips.

Further, the interlayer insulating layer 60 includes a first insulating layer 601 made of an inorganic material and a second insulating layer made 602 of an organic resin material, which are sequentially disposed over the pattern layer including the thin film transistors 20, the data lines 40 and the gate lines 30, and the raised strips are disposed on the second insulating layer 602.

Here, the step of forming second insulating layer 602 made of an organic resin material on the substrate formed with the first insulating layer 601 thereon specifically includes:

step S201 of forming a layer of organic resin material on the first insulating layer 601 made of an inorganic material, and coating photoresist 110 on the substrate formed with the layer of organic resin material thereon;

step S202 of exposing and developing the substrate coated with the photoresist 110 thereon by using a half-tone mask 100 or a gray tone mask so as to form a photoresist fully-remained portion 110a, a photoresist half-remained portion, and a photoresist fully-removed portion 110c.

The photoresist fully-remained portion 110a corresponds to regions of the raised strips, the photoresist fully-removed portion 110c corresponds to drain regions 202 of the thin film transistors 20, and the photoresist half-remained portion 110b corresponds to other regions

Here, the photoresist 110 includes positive photoresist, that is, the photoresist fully-remained portion 110a corresponds to a fully opaque portion 100a of the half-tone mask 100 or the gray tone mask, the photoresist half-remained portion 110b corresponds to a translucent portion 100b of the half-tone mask 100 or the gray tone mask, and the photoresist fully-removed portion 110c corresponds to a fully transparent portion 100c of the half-tone mask 100 or the gray tone mask.

In step S203 the photoresist fully-removed portion 110c, the photoresist half-remained portion 110b, and the photoresist fully-remained portion 11a are etched so as to form the second insulating layer 602.

Specifically, the above step S203 may include:
step S2031: exposed portions of the first insulating layer 601 made of inorganic material and the layer of organic resin material exposed from the photoresist fully-removed portion 110c are etched to expose regions of the drains 202 of the thin film transistors 20;

step S2032: the photoresist of the photoresist half-remained portion 110b is removed by using an ashing process, and then the exposed layer of organic resin material is etched so as to form other flat regions of the second insulating layer 602 by controlling process parameters such as etching time, etching rate and the like;

step S2033: the photoresist fully-remained portion 110a is removed to form the second insulating layer 602 including the raised strips.

Here, the organic resin material may includes a positive photoresist material or a negative photoresist material.

The positive photoresist material is a material which is not dissolved in a developing solution before exposure and becomes dissolvable in the developing solution after exposure; the negative photoresist material is a material which is dissolvable in a developing solution before exposure and becomes indissolvable in the developing solution after exposure.

Here, the step of forming second insulating layer 602 made of a positive photoresist material or a negative photoresist material on the substrate formed with the first insulating layer 601 thereon specifically includes:

Step S301: as shown in FIG. 16, positive photoresist 110 or negative photoresist 111 is coated on the first insulating layer 601 made of an inorganic material.

Note that, when forming raised strips on the second insulating layer 602 in subsequent processes, the second insulating layer 602 including the raised strips can be formed only by exposing and developing the positive photoresist 110 or the negative photoresist 11 by using photosensitive characterstics thereof. Thus, regions of the drains 202 of the thin film transistors 20 should be exposed from the formed first insulating layer 601 before the step S301.

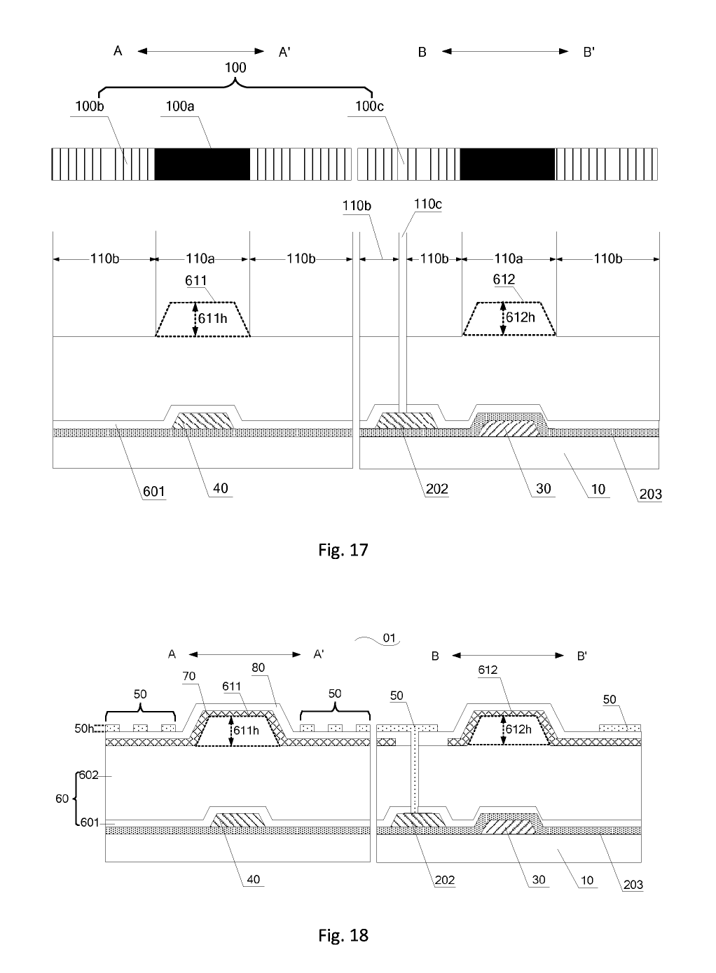

S302: as shown in FIG. 17, the substrate formed with the positive photoresist 110 or the negative photoresist 111 thereon is exposed and developed by using a half-tone mask 100 or gray tone mask so as to form a photoresist fully-remained portion 110a, a photoresist half-remained portion 110b, and a photoresist fully-removed portion 110c, thereby forming the second insulating layer 602 including the raised strips.

Here, the photoresist fully-remained portion 110a corresponds to regions of the raised strips, the photoresist fully-removed portion 110c corresponds to drain regions 202 of the thin film transistors 20, and the photoresist half-remained portion 110b corresponds to other regions, thereby forming the second insulating layer.

Here, the positive photoresist 110 is only described as an example in FIG. 17. In case that the negative photoresist 111 is used, since the negative photoresist 111 has an opposite photosensitivity to the positive photoresist 110. That is, after exposing and developing the negative photoresist 111, the negative photoresist 111 also forms a photoresist fully-remained portion 110a, a photoresist half-remained portion 110b, and a photoresist fully-removed portion 110c, wherein, the photoresist fully-remained portion 110a corresponds to the fully transparent portion 100c of the half-tone mask 100 or the gray tone mask, the photoresist half-remained portion 110b corresponds to the translucent portion 100b of the half-tone mask 100 or the gray tone mask, and the photoresist fully-removed portion 110c corresponds to fully opaque portion 100a of the half-tone mask 100 or the gray tone mask.

A particular embodiment will be provided below to describe the above array substrate 01 and the method of manufacturing the same:

A particular embodiment of the present invention provides an array substrate 01. As shown in FIG. 3, FIG. 9(a) and FIG. 18, the array substrate 01 includes: a substrate 10; bottom-gate type thin film transistors 20, data lines 40, gate lines 30 disposed on the substrate 10; an interlayer insulating layer 60 including raised strips and disposed on a pattern layer including the thin film transistors 20, the data lines 40 and the gate lines 30; a plate common electrode 70 disposed on the interlayer insulating layer 60; a passivation layer 80 disposed on a pattern layer including the common electrode 70; and pixel electrodes 50 having a slit structure or a comb-like structure disposed on the passivation layer 80.

Here, since the pixel electrodes 50 need to be electrically connected with drains 202 of the thin film transistors 20, through holes are provided in the passivation layer 80 and the interlayer insulating layer 60 to expose the drains 202 as shown in FIG. 9(a).

With reference to FIG. 9(a) and FIG. 18, the interlayer insulating layer 60 includes a first insulating layer 601 made of a silicon nitride material and a second insulating layer 602 made of a positive photoresist material, and the raised strips are disposed on the second insulating layer 602.

Preferably, the raised strips includes a plurality of first raised strips 611 and a plurality of second raised strips 612, wherein the first raised strips 611 are at least disposed in a region between two pixel electrodes 50 adjacent to each other in the first direction, and are not overlapped with adjacent pixel electrodes 50 adjacent to the first raised strip 611. The second raised strip 612 are at least disposed in a region between adjacent pixel electrodes 50 adjacent to each other in the second direction perpendicular to the first direction, and are not overlapped with adjacent pixel electrodes 50 adjacent to the second raised strips 612. The height 611h of the first raised strips and the height 612h of the second raised strips are the same in the direction perpendicular to the substrate 10, and larger than the height 50h of the pixel electrodes.

As shown in FIG. 3, when a size of the pixel unit surrounded by the data lines 40 and the gate lines 30 is continuously reduced to cause a distance between adjacent pixel electrodes 50 to be continuously reduced, the first raised strips 611 can be used to isolate an interference of electric field between adjacent pixel electrodes 50 in the first direction, and correspondingly, the second raised strip 612 can be used to isolate an interference of electric field between adjacent pixel electrodes 50 in the second direction, thereby avoiding phenomena such as color mixing and light leakage between adjacent pixel units in the display apparatus including an array substrate, and improving display effect of the display apparatus.

Considering that when both of distances between the first raised strips 611 and the pixel electrodes 50 adjacent thereto and between the second raised strip 612 and the pixel electrodes 50 adjacent thereto are smaller, a more effective effect of isolating the above interference of electric field can be achieved. Thus, widths of the first raised strips 611 in the first direction are set to be equal to or larger than those of the data lines 40, and widths of the second raised strips 612 in the second direction are set to be equal to or larger than those of the gate lines 30, as shown in FIG. 9a.

Further, adjacent pixel electrodes 50 are arranged symmetrically relative to a midline of a corresponding one of the first raised strips 611 in the first direction, and adjacent pixel electrodes 50 are arranged symmetrically relative to a midline of a corresponding one of the second raised strips 612 in the second direction. As such, the first raised strips 611 have the same effect of isolating the interference of electric field for two pixel electrodes 50 adjacent thereto, and the second raised strips 612 have the same effect of isolating the interference of electric field for two pixel electrodes 50 adjacent thereto. Therefore, when the above array substrate is applied to a display apparatus, the color mixing phenomenon between adjacent pixel units in the display apparatus can be more effectively reduced, thereby improving display effects of the display apparatus.

The array substrate 01 according to the above particular embodiment can be manufactured for example by the following method, including following steps:

At step S401, bottom-gate type thin film transistors 20, data lines 40 and gate lines 30 are formed on a substrate 10. Here, processes for forming the bottom-gate type thin film transistors 20, the data lines 40 and the gate lines 30 can use the manufacturing processes in the prior art, and thus will not be repeatedly described herein.

At step S402, a first insulating layer 601 made of a silicon nitride material is formed on the substrate after the above step S401, and the drains 202 are exposed from the first insulating layer 601.

At step S403, a layer of positive photoresist 110 is coated on the substrate after the above step S402.

At step S404, the substrate formed with the positive photoresist 110 thereon is exposed and developed by using a half-tone mask 100 so as to form a photoresist fully-remained portion 110a, a photoresist half-remained portion 110b, and a photoresist fully-removed portion 110c.

Here, the photoresist fully-remained portion 110a corresponds to regions of the raised strips, the photoresist fully-removed portion corresponds to regions of the drains 202 exposed from the first insulating layer 601, and the photoresist half-remained portion 110b corresponds to other regions, so that the second insulating layer 602 is formed.

At step S405, a common electrode 70 and a passivation layer 80 are sequentially formed on the substrate after the above step S404, wherein the drains 202 are exposed from the passivation layer 80.

At step S406, pixel electrodes 50 are formed on substrate after the above step S405 to be electrically connected with the drains 202 exposed from the passivation layer 80.

Thus, the array substrate 01 shown in FIG. 18 can be obtained through the above steps S401˜S406.

An embodiments of the present invention provides a display apparatus, including the above array substrate 01. When the display apparatus displays images, since in the array substrate 01, the first raised strips 611 are disposed between adjacent pixel electrodes 50 adjacent to each other in the first direction, and the height 611h of the first raised strips in the direction perpendicular to the substrate 10 is larger than the height 50h of the pixel electrodes, a remarkable effect of isolating the interference of electric field between adjacent pixel electrodes 50 in the first direction can be achieved, thereby avoiding phenomena such as color mixing and light leakage in the display apparatus including an array substrate, and improving display effects of the display apparatus.

Specifically, the above display apparatus may be a liquid crystal display apparatus, for example, may be a liquid crystal display, a liquid crystal television, a digital photo frame, a mobile phone, a tablet computer, or any other products or components having a displaying function.

It will be understood by those skilled in the art from the above description that all figures in embodiments of the present invention are compendious and schematic views of the array substrate for clearly describing structures associated with the inventive concepts of the present invention, and other structures which are not associated with the inventive concepts of the present invention are common-known structures and thus not shown or just partially shown in the figures.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

What is claimed is:

1. An array substrate, including:
a substrate;
thin film transistors, data lines, gate lines and pixel electrodes disposed on the substrate, wherein the gate lines extend in a first direction, and the data lines extend in a second direction;
an interlayer insulating layer, disposed below the pixel electrodes, and provided with insulating raised strips protruding in a thickness direction of the substrate towards a space between adjacent pixel electrodes, wherein a projection of each raised strip on the substrate in the thickness direction is not overlapped with those of the adjacent pixel electrodes.

2. The array substrate according to claim 1, wherein:
surfaces of the raised strips far away from the interlayer insulating layer are in the same plane as surfaces of the pixel electrodes far away from the interlayer insulating layer, or protruded beyond a plane in which the surfaces of the pixel electrodes far away from the interlayer insulating layer lie.

3. The array substrate according to claim 1, wherein:
the raised strips include a plurality of first raised strips, each of which extends in the second direction and is disposed between two pixel electrodes which are adjacent to each other in the first direction.

4. The array substrate according to claim 3, wherein:
in the first direction, widths of the first raised strips are equal to or larger than those of the data lines.

5. The array substrate according to claim 3, wherein:
the raised strips further include a plurality of second raised strips, each of which extends in the first direction and is disposed between two pixel electrodes which are adjacent to each other in the second direction.

6. The array substrate according to claim 3, wherein:
the pixel electrodes are arranged into a plurality of columns, each of which extends in the second direction; and
each of the first raised strips arranged between two adjacent columns of pixel electrodes is formed as a single raised strip.

7. The array substrate according to claim 1, wherein:
the raised strips include a plurality of second raised strips, each of which extends in the first direction and is disposed between two pixel electrodes which are adjacent to each other in the second direction.

8. The array substrate according to claim 7, wherein:
in the second direction, widths of the second raised strips are equal to or larger than those of the gate lines.

9. The array substrate according to claim 7, wherein:
the pixel electrodes are arranged into a plurality of rows, each of which extends in the first direction; and
each of the second raised strips arranged between two adjacent rows of pixel electrodes is formed as a single raised strip.

10. The array substrate according to claim 9, wherein:
the raised strips further include a plurality of first raised strips, each of which extends in the second direction and is disposed between two pixel electrodes which are adjacent to each other in the first direction.

11. The array substrate according to claim 1, wherein:
the two adjacent pixel electrodes are arranged symmetrically relative to a midline of one corresponding raised strip.

12. The array substrate according to claim 1, wherein:
the interlayer insulating layer is disposed between a pattern layer including the thin film transistors, the data lines, and the gate lines and a pattern layer including a common electrode of the array substrate.

13. The array substrate according to claim 1, wherein:
the interlayer insulating layer includes a first insulating layer made of an inorganic material and a second insulating layer made of an organic resin material, which are sequentially disposed over a pattern layer including the thin film transistors, the data lines, and the gate lines, and
the raised strips are disposed on the second insulating layer.

14. The array substrate according to claim 13, wherein
the organic resin material includes a positive photoresist material or a negative photoresist material.

15. A display apparatus, including the array substrate according to claim 1.

16. A method of manufacturing an array substrate, including steps of:
forming thin film transistors, data lines, and gate lines on a substrate, wherein the gate lines extend in a first direction, and the data lines extend in a second direction;
forming an interlayer insulating layer including insulating raised strips on the substrate formed with the thin film transistors, the data lines, and the gate lines thereon; and
forming pixel electrodes on the substrate formed with interlayer insulating layer including the raised strips thereon,
wherein the raised strips protrude in a thickness direction of the substrate towards a space between adjacent pixel electrodes, and a projection of each raised strip on the substrate in the thickness direction is not overlapped with those of the adjacent pixel electrodes.

17. The method according to claim 16, wherein:
surfaces of the raised strips far away from the interlayer insulating layer are in the same plane as surfaces of the pixel electrodes far away from the interlayer insulating layer, or protruded beyond a plane in which the surfaces of the pixel electrodes far away from the interlayer insulating layer lie.

18. The method according to claim 16, wherein the step of forming the interlayer insulating layer including the insulating raised strips on the substrate formed with the thin film transistors, the data lines, and the gate lines thereon includes steps of:
forming an insulating material layer on the substrate formed with a pattern layer including the thin film transistors, the data lines, and the gate lines thereon;
coating photoresist on the substrate formed with the insulating material layer thereon;
exposing and developing the substrate coated with the photoresist thereon by using a half-tone mask or a gray tone mask so as to form a photoresist fully-remained portion corresponding to regions of the raised strips, a photoresist fully-removed portion corresponding to drain regions of the thin film transistors, and a photoresist half-remained portion corresponding to other regions;
etching the photoresist fully-removed portion, the photoresist half-remained portion and the photoresist fully-remained portion, so as to form the interlayer insulating layer including the raised strips.

19. The method according to claim 16, wherein the step of forming the interlayer insulating layer including the insulating raised strips on the substrate formed with the thin film transistors, the data lines, and the gate lines thereon includes a step of:
on the substrate formed with a pattern layer including the thin film transistors, the data lines, and the gate lines thereon, sequentially forming a first insulating layer made of an inorganic material and a second insulating layer made of an organic resin material, wherein the raised strip are formed on the second insulating layer.

20. The method according to claim 19, wherein the step of forming the second insulating layer made of an organic resin material on the substrate formed with the first insulating layer thereon includes steps of:
forming a layer of organic resin material on the first insulating layer made of an inorganic material, and coating photoresist on the substrate formed with the layer of organic resin material thereon;
exposing and developing the substrate coated with the photoresist thereon by using a half-tone mask or a gray tone mask so as to form a photoresist fully-remained portion corresponding to regions of the raised strips, a photoresist fully-removed portion corresponding to drain regions of the thin film transistors, and a photoresist half-remained portion corresponding to other regions;
etching the photoresist fully-removed portion, the photoresist half-remained portion and the photoresist fully-remained portion, so as to form the second insulating layer.
